(19) United States
(12) Patent Application Publication
(10) Pub. No.: US 2024/0339809 A1
(43) Pub. Date: Oct. 10, 2024

(54) SEMICONDUCTOR LASER MODULE, LASER OSCILLATOR, AND LASER MACHINING APPARATUS

(71) Applicant: Mitsubishi Electric Corporation, Chiyoda-ku, Tokyo (JP)

(72) Inventors: Yuki OKAMOTO, Tokyo (JP); Daisuke MORITA, Tokyo (JP)

(73) Assignee: Mitsubishi Electric Corporation, Chiyoda-ku, Tokyo (JP)

(21) Appl. No.: 18/576,419

(22) PCT Filed: Aug. 29, 2022
(86) PCT No.: PCT/JP2022/032378

§ 371 Date: Jan. 4, 2024

(30) Foreign Application Priority Data
Aug. 30, 2021 (JP) 2021-139992

(51) Int. Cl. H01S 5/024; B23K 26/36; H01S 5/02253; H01S 5/023; H01S 5/40

(52) U.S. Cl. CPC H01S 5/02469; B23K 26/36; H01S 5/023; H01S 5/4025; H01S 5/02253

(57) ABSTRACT

A semiconductor laser module includes: a heat sink; a first electrode disposed in a first region of the heat sink; an insulating layer disposed on the first electrode; a submount disposed in a second region of the heat sink, the second region being different from the first region, the submount being electrically and thermally conductive; a laser diode element disposed on the submount, the laser diode element emitting a laser beam; a feed structure disposed on the laser diode element, the feed structure being electrically and thermally conductive; and a second electrode provided on the insulating layer and the feed structure such that the second electrode is in contact with the insulating layer and the feed structure. A positional relationship between the heat sink, the first electrode, the insulating layer, and the second electrode is fixed by an adhesive.

### FIELD

The present disclosure relates to a semiconductor laser module that outputs a laser beam, a laser oscillator, and a laser machining apparatus.

### BACKGROUND

A high-output laser device typified by a light source for a laser machining apparatus includes a plurality of semiconductor laser modules that emit laser beams. Patent Literature 1 discloses an example of a configuration of such a semiconductor laser module. The semiconductor laser module described in Patent Literature 1 includes a heat sink, a first electrode, and a second electrode. The first electrode is disposed on the heat sink, and has a recess on an upper surface on a front side. The second electrode is disposed on the first electrode via an insulating layer, at a position other than a position where the recess of the first electrode has been formed. In the semiconductor laser module described in Patent Literature 1, a submount, a semiconductor laser element, and a conductive bump are placed in this order in the recess of the first electrode, and the conductive bump is connected to the second electrode covering the recess. The second electrode and the first electrode are fixed by a first fastening member, and the first electrode and the heat sink are fixed by a second fastening member.

### CITATION LIST

### Patent Literature

Patent Literature 1: WO 2019/009086 A

### SUMMARY OF INVENTION

### Problem to be Solved by the Invention

However, in the semiconductor laser module described in Patent Literature 1, the first electrode and the second electrode are fastened by the first fastening member at two positions in a width direction on the front side, and the heat sink and the first electrode are fastened by the second fastening member at two positions in the width direction. In order to secure positions where the first fastening member and the second fastening member are disposed in such a way as to avoid interference between the first fastening member and the second fastening member, there has been a limit on reduction in the size of the first electrode and the second electrode in the width direction in the semiconductor laser module described in Patent Literature 1. Thus, it has been difficult to further miniaturize a laser device including a plurality of semiconductor laser modules.

The present disclosure has been made in view of the above, and an object of the present disclosure is to obtain a semiconductor laser module that can be reduced in size in a width direction as compared with the conventional one.

### Means to Solve the Problem

In order to solve the above-described problem and achieve the object, a semiconductor laser module according to the present disclosure includes: a heat sink; a first electrode disposed in a first region of the heat sink; an insulating layer disposed on the first electrode; a submount disposed in a second region of the heat sink, the second region being different from the first region, the submount being electrically and thermally conductive; a laser diode element disposed on the submount, the laser diode element emitting a laser beam; a feed structure disposed on the laser diode element, the feed structure being electrically and thermally conductive; and a second electrode provided on the insulating layer and the feed structure such that the second electrode is in contact with the insulating layer and the feed structure. A positional relationship between the heat sink, the first electrode, the insulating layer, and the second electrode is fixed by an adhesive.

### Effects of the Invention

The semiconductor laser module according to the present disclosure has the effect of enabling size to be reduced in the width direction as compared with the conventional technique.

### BRIEF DESCRIPTION OF DRAWINGS

FIG. 1 is a perspective view of a semiconductor laser module according to a first embodiment, which schematically shows an example of a configuration of the semiconductor laser module.

FIG. 2 is a partial cross-sectional view of the semiconductor laser module according to the first embodiment, which schematically shows the example of the configuration of the semiconductor laser module.

FIG. 3 is a front view of the semiconductor laser module according to the first embodiment, which schematically shows the example of the configuration of the semiconductor laser module.

FIG. 4 is a partial cross-sectional view of a semiconductor laser module according to a first embodiment, which schematically shows an example of a configuration of the semiconductor laser module, and is a cross-sectional view taken along line IV-IV of FIG. 2.

FIG. 5 is a diagram schematically showing an example of a configuration of a laser oscillator according to a second embodiment.

FIG. 6 is a partial front view of the laser oscillator according to the second embodiment, which schematically shows an example of a configuration of the laser oscillator.

FIG. 7 is a front view of a semiconductor laser module included in the laser oscillator according to the second embodiment, which schematically shows an example of a configuration of the semiconductor laser module.

FIG. 8 is a front view of the semiconductor laser module included in the laser oscillator according to the second embodiment, which schematically shows another example of the configuration of the semiconductor laser module.

FIG. 9 is a front view of the semiconductor laser module included in the laser oscillator according to the second embodiment, which schematically shows still another example of the configuration of the semiconductor laser module.

FIG. 10 is a diagram schematically showing an example of a configuration of a laser machining apparatus according to the second embodiment.

### DESCRIPTION OF EMBODIMENTS

Hereinafter, a semiconductor laser module, a laser oscillator, and a laser machining apparatus according to embodiments of the present disclosure will be described in detail with reference to the drawings.

### First Embodiment

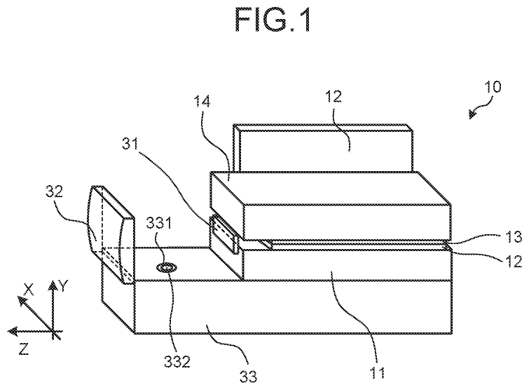

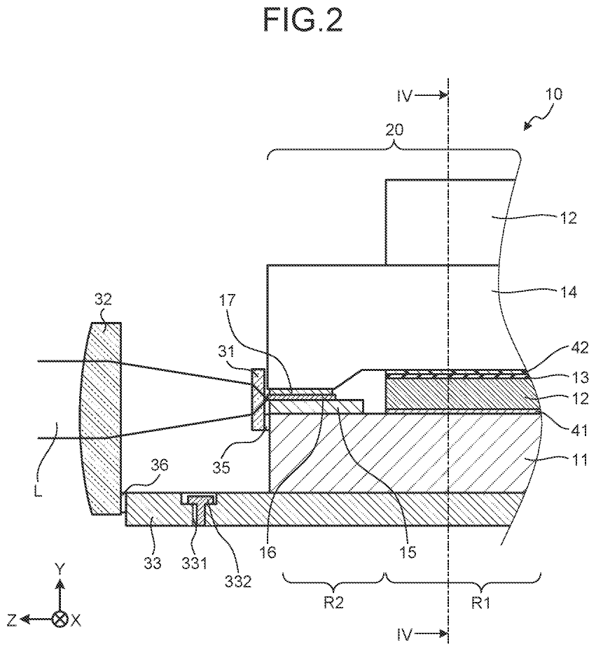

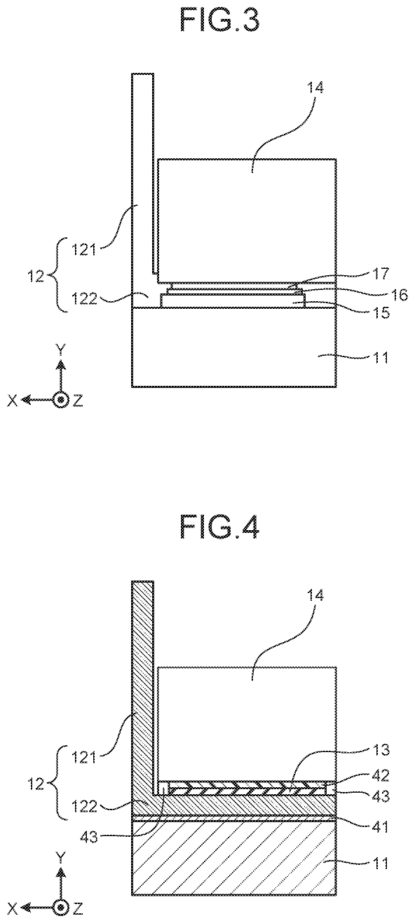

FIG. 1 is a perspective view of a semiconductor laser module according to a first embodiment, which schematically shows an example of a configuration of the semiconductor laser module. FIG. 2 is a partial cross-sectional view of the semiconductor laser module according to the first embodiment, which schematically shows the example of the configuration of the semiconductor laser module. FIG. 3 is a front view of the semiconductor laser module according to the first embodiment, which schematically shows the example of the configuration of the semiconductor laser module. FIG. 4 is a partial cross-sectional view of a semiconductor laser module according to a first embodiment, which schematically shows an example of a configuration of the semiconductor laser module, and is a cross-sectional view taken along line IV-IV of FIG. 2. Hereinafter, a Z-axis direction is defined as a direction in which a laser beam L is emitted, a Y-axis direction is defined as a direction perpendicular to the Z-axis and a direction in which members included in a semiconductor laser module 10 are stacked, and an X-axis direction is defined as a direction perpendicular to both the Z-axis and the Y-axis. Furthermore, a relationship between relative positions of two objects in the Y-axis direction is represented as upper and lower. In addition, a plane perpendicular to the Z-axis direction on which a laser diode element 16 is provided is defined as a front face. A relationship between relative positions of two objects in the Z-axis direction is represented as front and rear. FIG. 2 corresponds to a YZ cross section of FIG. 1. In addition, FIG. 3 illustrates a front view of the semiconductor laser module from which a fast axis collimator (FAC) 31 and a slow axis collimator (SAC) 32 have been removed.

The semiconductor laser module 10 includes a heat sink 11, an anode electrode 12, an insulating sheet 13, a cathode electrode 14, a submount 15, the laser diode element 16, and a feed structure 17.

The heat sink 11 is a heat dissipation member for preventing the laser diode element 16 from increasing in temperature. The heat sink 11 has a tabular or rectangular parallelepiped structure extending in the Z-axis direction. The heat sink 11 is made of a material having good thermal conductivity. Here, the heat sink 11 is desirably made of a material also having electrical conductivity. In one example, the heat sink 11 is made of copper (Cu). Furthermore, in one example, a water passage through which cooling water flows is provided inside the heat sink 11. An upper surface of the heat sink 11 has an electrode placement region R1 and an element placement region R2. The electrode placement region R1 corresponds to a first region. The element placement region R2 corresponds to a second region.

The anode electrode 12 having an L-shape in an XY plane is disposed in the electrode placement region R1 of the heat sink 11. The anode electrode 12 is fixed to the electrode placement region R1 of the heat sink 11 with an adhesive 41. When an insulating adhesive is used as the adhesive 41, it is desirable to maintain electrical connection by fixing the anode electrode 12 to the heat sink 11 by fillet adhesion. The anode electrode 12 includes an L-shaped member having a first portion 121 and a second portion 122. The first portion 121 is a tabular portion parallel to a YZ plane. The second portion 122 is a tabular portion parallel to a ZX plane. The anode electrode 12 is an electrode that is connected to a power supply (not illustrated) and supplies current to the laser diode element 16. The anode electrode 12 is connected to a p-type semiconductor side of the laser diode element 16. The anode electrode 12 and the heat sink 11 are electrically connected. An example of the anode electrode 12 is copper. In one example, the anode electrode 12 corresponds to a first electrode.

The cathode electrode 14 is disposed on the second portion 122 of the anode electrode 12 via the insulating sheet 13. The cathode electrode 14 and the heat sink 11 are substantially identical in shape and size in the ZX plane. In other words, the cathode electrode 14 has a structure projecting forward, that is, projecting in the positive direction of the Z-axis, with respect to the second portion 122 of the anode electrode 12 on the ZX plane. In the X-axis direction, the cathode electrode 14 is disposed at a distance from the first portion 121 of the anode electrode 12 so that the cathode electrode 14 does not come into contact with the first portion 121 of the anode electrode 12. The cathode electrode 14 is an electrode that is connected to the power supply (not illustrated) and supplies current to the laser diode element 16. The cathode electrode 14 is connected to an n-type semiconductor side of the laser diode element 16. The cathode electrode 14 also has a function of dissipating heat generated by the laser diode element 16. An example of the cathode electrode 14 is copper. In one example, the cathode electrode 14 corresponds to a second electrode.

The insulating sheet 13 is an insulating layer disposed on the second portion 122 of the anode electrode 12 and provided so as to insulate the anode electrode 12 and the cathode electrode 14 from each other. In the first embodiment, the insulating sheet 13 is smaller in size than the second portion 122 of the anode electrode 12. The insulating sheet 13 is disposed on the second portion 122 such that the insulating sheet 13 does not extend beyond the second portion 122. The insulating sheet 13 is bonded to the cathode electrode 14 with an adhesive 42. In addition, a part of the second portion 122 is not in contact with the insulating sheet 13. The part of the second portion 122 is bonded to the cathode electrode 14 with an adhesive 43. An insulating adhesive having no electrical conductivity is used as the adhesive 43 so as to electrically insulate the anode electrode 12 and the cathode electrode 14 from each other. As described above, a positional relationship between the heat sink 11, the anode electrode 12, the insulating sheet 13, and the cathode electrode 14 is fixed by the adhesives 41, 42, and 43.

The laser diode element 16 is disposed in the element placement region R2 of the heat sink 11 via the submount 15. The submount 15 is fixed on the element placement region R2 of the heat sink 11. In one example, the submount 15 is fixed to the heat sink 11 with a conductive adhesive (not illustrated). The submount 15 is an intermediate member for alleviating stress generated in the laser diode element 16 due to a difference in linear expansion coefficient between the heat sink 11 and the laser diode element 16. That is, the submount 15 desirably has a linear expansion coefficient between a linear expansion coefficient of the laser diode element 16 and a linear expansion coefficient of the heat sink 11. In addition, the submount 15 is thermally conductive so as to transfer heat from the laser diode element 16 to the heat sink 11, and is also electrically conductive so as to obtain electrical connection with the anode electrode 12 via the heat sink 11. Examples of a material for the submount 15 include copper tungsten (CuW) and aluminum nitride (AlN).

The laser diode element 16 is disposed and fixed on the submount 15. The laser diode element 16 is an end surface-emitting laser that has a p-n junction in which a p-type semiconductor layer and an n-type semiconductor layer are stacked in the Y-axis direction and emits the laser beam L in the Z-axis direction. As an example, gallium arsenide (GaAs) is used as a base material of the laser diode element 16, and indium gallium arsenide (InGaAs) is used as an active layer of the laser diode element 16. In the Z-axis direction, the laser diode element 16 is disposed such that a front end surface of the laser diode element 16 is substantially aligned with front end surfaces of the heat sink 11 and the cathode electrode 14.

The feed structure 17 that is electrically and thermally conductive is disposed on the laser diode element 16. The feed structure 17 electrically connects the laser diode element 16 and the cathode electrode 14, and an area of contact between the feed structure 17 and the laser diode element 16 is sufficiently large. As a result, the feed structure 17 has a function of improving the amount of heat dissipation from an upper surface of the laser diode element 16.

A space above the element placement region R2 of the heat sink 11 is covered with the cathode electrode 14. The submount 15, the laser diode element 16, and the feed structure 17 are disposed in the space between the heat sink 11 and the cathode electrode 14.

The anode electrode 12 is electrically connected to the laser diode element 16 via the adhesive 41, the heat sink 11, and a submount 15. The cathode electrode 14 is electrically connected to the laser diode element 16 via the feed structure 17.

Note that the case where the heat sink 11 is electrically conductive has been described above, but an insulating layer may be partially included in the heat sink 11. In this case, an upper portion of the heat sink 11 just needs to be made of an electrically conductive material. Alternatively, an electrically conductive material just needs to be provided between the heat sink 11 and the anode electrode 12 and between the heat sink 11 and the submount 15.

A structure that includes the heat sink 11, the anode electrode 12, the insulating sheet 13, the cathode electrode 14, the submount 15, the laser diode element 16, and the feed structure 17, and emits the laser beam L is hereinafter referred to as a laser emission unit 20.

In addition, the semiconductor laser module 10 includes the FAC 31, the SAC 32, and the manifold 33.

The FAC 31 is an optical component that is provided on a Z-axis-direction end surface of the laser diode element 16 of the laser emission unit 20 and collimates a fast-axis direction component of the laser beam L emitted from the laser diode element 16. In one example, the FAC 31 is fixed to a Z-axis-direction end surface of the heat sink 11 with an adhesive 35. With reference to the shape, diameter, and the like of the laser beam L emitted from the laser diode element 16, a position of the FAC 31 is adjusted both in the Y-axis direction and in the Z-axis direction, and an angle of rotation of the FAC 31 around the Z-axis is adjusted. Then, the FAC 31 is fixed to the end surface of the heat sink 11 with the adhesive 35 such that the FAC 31 is disposed at the position adjusted both in the Y-axis direction and in the Z-axis direction, and that the adjusted angle of rotation around the Z-axis is achieved. In this manner, the FAC 31 is bonded after alignment. This means that alignment of the laser emission unit 20 has been completed.

The SAC 32 is an optical component that collimates a slow-axis direction component of the laser beam L having passed through the FAC 31.

The manifold 33 serves as a base material of the semiconductor laser module 10, and is fixed to a housing of a laser machining apparatus. The laser emission unit 20, more specifically, the heat sink 11 is supported and fixed on an upper surface of the manifold 33. Furthermore, the manifold 33 is also a junction member having a water passage for introducing cooling water into the heat sink 11. A water passage for introducing cooling water into the heat sink 11 is provided in a manifold 33. The water passage is connected to a water passage provided in the heat sink 11. An example of a material of the manifold 33 is steel use stainless (SUS) 303.

In the Z-axis direction, a Z-axis direction end portion of the manifold 33 projects forward, that is, projects in a direction in which the laser beam L is emitted, with respect to the laser emission unit 20 on the manifold 33. The SAC 32 is fixed to this end portion with an adhesive 36.

In this example, the SAC 32 is fixed to a Z-axis-direction end surface of the manifold 33 with the adhesive 36 in such a way as to be located on an optical path of the laser beam L emitted from the laser diode element 16 and passing through the FAC 31. With reference to the shape, diameter, and the like of the laser beam L emitted from the laser diode element 16, a position of the SAC 32 is adjusted both in the Y-axis direction and in the Z-axis direction, and an angle of rotation of the SAC 32 around the Z-axis is adjusted. Then, the SAC 32 is fixed to the end surface of the manifold 33 with the adhesive 36 such that the SAC 32 is disposed at the position adjusted both in the Y-axis direction and in the Z-axis direction, and that the adjusted angle of rotation around the Z-axis is achieved. At this time, a surface perpendicular to the Z-axis direction in which the positioning likelihood of the SAC 32 is large is set as a bonding surface. This prevents deterioration of beam quality due to misalignment that occurs in a thickness direction at the time of curing of the adhesive 36. In this manner, the SAC 32 is bonded after alignment. This means that alignment of the semiconductor laser module 10 has been completed.

The manifold 33 has, in a region between the FAC 31 and the SAC 32, a through-hole 331 and a bolt 332. The through-hole 331 penetrates the manifold 33 in the Y-axis direction. The bolt 332 is a fixing member inserted into the through-hole 331. Furthermore, a screw hole into which the bolt 332 is screwed is provided at an installation position of the semiconductor laser module 10 in the housing of the laser machining apparatus (not illustrated). A diameter of the through-hole 331 is set in such a way as to be larger than a diameter of the screw hole and smaller than a diameter of a head of the bolt 332. The through-hole 331 provided in the manifold 33 is aligned with the screw hole provided in the laser machining apparatus, and then, the bolt 332 is inserted into the through-hole 331. Then, the angle of the manifold 33 around the Y-axis is adjusted, and the bolt 332 is screwed into the screw hole. As a result, the manifold 33 is fixed at a predetermined position on the housing of the laser machining apparatus. Note that since the diameter of the through-hole 331 is larger than the diameter of the screw hole, the manifold 33 can be moved in the ZX plane within a range of the diameter of the through-hole 331 in a state where the bolt 332 is loosened. Furthermore, it is also possible to rotate the manifold 33 around the Y-axis.

In the first embodiment, the anode electrode 12 is fixed on the heat sink 11 with the adhesive 41, and the cathode electrode 14 is fixed on the second portion 122 of the anode electrode 12 with the adhesives 42 and 43 via the insulating sheet 13. As a result, unlike the technique described in Patent Literature 1, it is not necessary to secure positions where fastening members are disposed in fixing the heat sink 11, the anode electrode 12, and the cathode electrode 14. Therefore, the heat sink 11, the anode electrode 12, and the cathode electrode 14 can be reduced in width, that is, reduced in size in an X-axis direction, as compared with the conventional technique. In other words, an extra width for fixation by means of fastening members need not be added to the width of the laser diode element 16 according to required laser output. Thus, the widths of the heat sink 11, the anode electrode 12, and the cathode electrode 14 may be set such that the heat sink 11, the anode electrode 12, and the cathode electrode 14 are slightly larger in width than the laser diode element 16.

### Second Embodiment

In the semiconductor laser module described in Patent Literature 1, the first electrode and the second electrode are fastened by the fastening members. Thus, there has been a limit on reduction in size in the width direction. Therefore, there has been a limit on reduction in size in the width direction also in the case of a laser oscillator including a plurality of such semiconductor laser modules arranged in the width direction. Thus, there is a demand for further miniaturization of a laser oscillator.

In the first embodiment, the semiconductor laser module 10 has been described in which the heat sink 11 and the anode electrode 12 are fixed by the adhesive 41, and the second portion 122 of the anode electrode 12, the insulating sheet 13, and the cathode electrode 14 are fixed by the adhesives 42 and 43. Use of the above-described semiconductor laser module 10 allows a laser oscillator to be further miniaturized as compared with the conventional one. In a second embodiment, a laser oscillator including the semiconductor laser module 10 described above will be described.

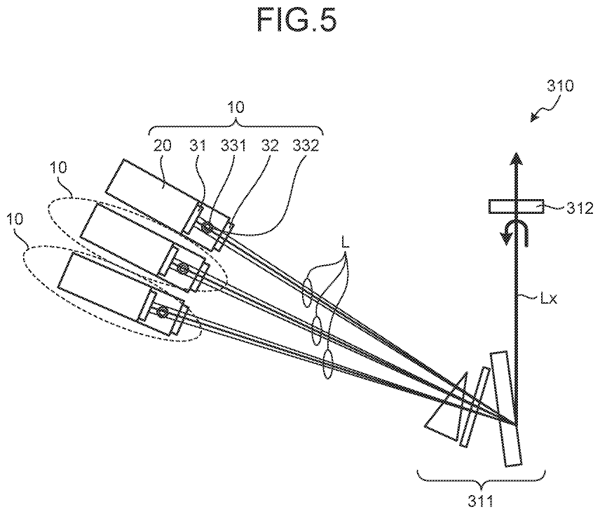

FIG. 5 is a diagram schematically showing an example of a configuration of a laser oscillator according to the second embodiment. A laser oscillator 310 emits a laser beam Lx. The laser oscillator 310 includes a plurality of the semiconductor laser modules 10, an optical coupler 311, and an external resonator mirror 312 in a housing (not illustrated). As described above, the semiconductor laser module 10 has the following structure. The FAC 31 is bonded to the laser emission unit 20, and the laser emission unit 20 is fixed to the manifold 33. Then, the SAC 32 is fixed to the manifold 33. The optical coupler 311 couples the laser beams L from the plurality of semiconductor laser modules 10. A prism, a diffraction grating, or the like is used as the optical coupler 311. The external resonator mirror 312 transmits part of the laser beam Lx coupled by the optical coupler 311, and reflects the remaining part toward the semiconductor laser module 10. The external resonator mirror 312 forms an optical resonator, together with an emission surface of the laser diode element 16 of the semiconductor laser module 10, from which the laser beam L is emitted.

In FIG. 5, a through-hole 331 of the semiconductor laser module 10 is disposed such that the through-hole 331 is aligned with a screw hole provided at a predetermined position in the housing, and a bolt 332 is screwed into the screw hole. As a result, the semiconductor laser module 10 is fixed to the housing.

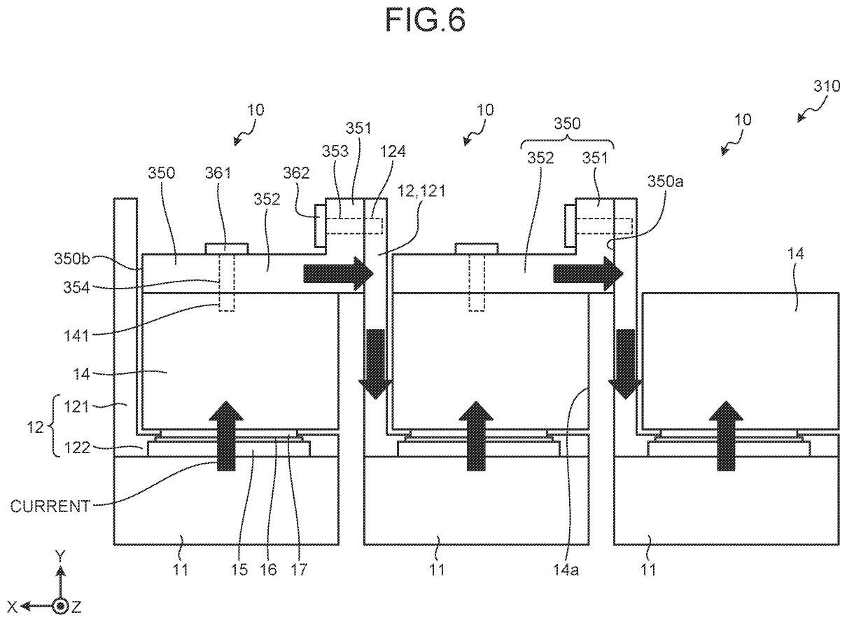

FIG. 6 is a partial front view of the laser oscillator according to the second embodiment, which schematically shows an example of a configuration of the laser oscillator. FIG. 6 schematically illustrates a plurality of the semiconductor laser modules 10 viewed from the front side. Note that the same constituent elements as those in the first embodiment are denoted by the same reference numerals, and description thereof will be omitted. As illustrated in FIG. 6, a screw hole 141 is provided at a predetermined position on an upper surface of the cathode electrode 14 of the semiconductor laser module 10. Furthermore, a screw hole 124 is also provided at a predetermined position on the first portion 121 of the anode electrode 12 of the semiconductor laser module 10.

The laser oscillator 310 further includes bus bars 350 which are electrically conductive coupling members. The bus bar 350 has an L-shape in the XY plane. The bus bar 350 includes an L-shaped member having a third portion 351 and a fourth portion 352. The third portion 351 is a tabular portion parallel to the YZ plane. The fourth portion 352 is a tabular portion parallel to the ZX plane. The bus bar 350 is disposed on the cathode electrode 14 of the semiconductor laser module 10 such that the fourth portion 352 is located on the upper surface of the cathode electrode 14, and that the third portion 351 is in contact with the first portion 121 of the anode electrode 12 of another semiconductor laser module 10 disposed adjacent to the above-described semiconductor laser module 10 in the X-axis direction.

A through-hole 353 penetrating the third portion 351 in a thickness direction is provided at a predetermined position on the third portion 351 of the bus bar 350. Furthermore, a through-hole 354 penetrating the fourth portion 352 in the thickness direction is provided at a predetermined position on the fourth portion 352 of the bus bar 350. The bus bar 350 is disposed on the cathode electrode 14 of the semiconductor laser module 10 such that the screw hole 141 provided in the cathode electrode 14 is aligned with the through-hole 354 of the fourth portion 352 of the bus bar 350, and that the screw hole 124 provided in the anode electrode 12 of the adjacent semiconductor laser module 10 is aligned with the through-hole 353 of the third portion 351 of the bus bar 350. Then, a fastening member such as a screw 361 is screwed into the through-hole 354 of the fourth portion 352 of the bus bar 350 and the screw hole 141 provided in the cathode electrode 14, and a fastening member such as a screw 362 is screwed into the through-hole 353 of the third portion 351 of the bus bar 350 and the screw hole 124 provided in the anode electrode 12 of the adjacent semiconductor laser module 10. Thus, the bus bar 350 is fixed on the cathode electrode 14 of the semiconductor laser module 10. Note that the through-hole 354 provided in the fourth portion 352 may be larger than a diameter of the screw 361, and the through-hole 353 provided in the third portion 351 may be larger than a diameter of the screw 362. As a result, when the screw 361 is inserted into the screw hole 141 of the cathode electrode 14 and is tightened, and when the screw 362 is inserted into the screw hole 124 of the anode electrode 12 of the adjacent semiconductor laser module 10 and is tightened, the position of the bus bar 350 can be finely adjusted in the ZX plane and the YZ plane. The screw 361 corresponds to a first fastening member, and the screw 362 corresponds to a second fastening member.

An end portion 350a, which is an X-axis negative side end portion of the bus bar 350, projects out with respect to an end portion 14a which is an X-axis negative side end portion of the cathode electrode 14. This is to maintain electrical connection with the first portion 121 of the anode electrode 12 of the adjacent semiconductor laser module 10. Furthermore, in the semiconductor laser module 10 provided with the bus bar 350, the bus bar 350 may be rotated and disposed in the ZX plane within a range in which an end portion 350b, which is an X-axis positive side end portion of the bus bar 350, does not come into contact with the first portion 121 of the anode electrode 12. As a result, even when the semiconductor laser module 10 and another semiconductor laser module 10 adjacent thereto are not arranged in parallel, it is possible to fasten the bus bar 350 to the cathode electrode 14 with the screw 361 and to fasten the bus bar 350 to the anode electrode 12 with the screw 362 while keeping the first portion 121 of the anode electrode 12 of the adjacent semiconductor laser module 10 in contact with the third portion 351 of the bus bar 350.

As described above, there is a possibility that the fourth portion 352 of the bus bar 350 may come into contact with the first portion 121 of the anode electrode 12 when the bus bar 350 is rotated in the ZX plane. Therefore, a method for preventing electrical contact between the bus bar 350 and the anode electrode 12 may be performed.

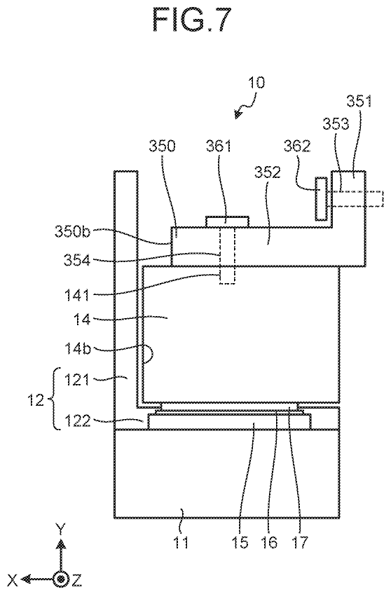

FIG. 7 is a front view of a semiconductor laser module included in the laser oscillator according to the second embodiment, which schematically shows an example of a configuration of the semiconductor laser module. FIG. 7 also schematically illustrates one of the plurality of semiconductor laser modules 10 illustrated in FIG. 5, viewed from the front side. In FIG. 7, the end portion 350b, which is the X-axis positive side end portion of the bus bar 350, is recessed with respect to an end portion 14b of the cathode electrode 14 in the X-axis negative direction. That is, in the X-axis direction, a distance between the first portion 121 of the anode electrode 12 and the end portion 350b of the bus bar 350, facing the anode electrode 12 is larger than a distance between the first portion 121 and the end portion 14b of cathode electrode 14, facing the anode electrode 12. As a result, the angle of rotation of the bus bar 350 in the ZX plane can be made larger than in the case of FIG. 6.

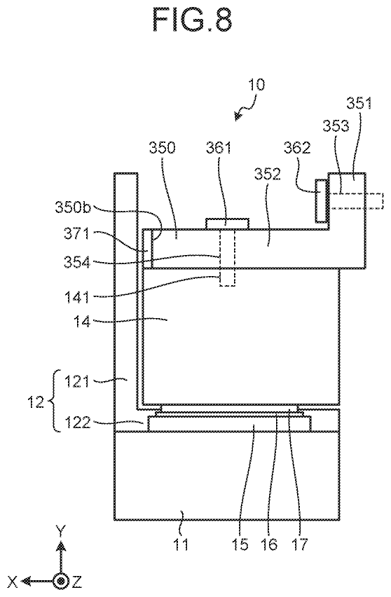

FIG. 8 is a front view of the semiconductor laser module included in the laser oscillator according to the second embodiment, which schematically shows another example of the configuration of the semiconductor laser module. FIG. 8 also schematically illustrates one of the plurality of semiconductor laser modules 10 illustrated in FIG. 5, viewed from the front side. In FIG. 8, the bus bar 350 includes an insulating layer 371 on the end portion 350b which is the X-axis positive side end portion of the fourth portion 352. With such a configuration, even when the end portion 350b, which is the X-axis positive side end portion of the fourth portion 352 of the bus bar 350, comes into contact with the first portion 121 of the anode electrode 12, it is possible to prevent the cathode electrode 14 and the anode electrode 12 from being short-circuited via the bus bar 350.

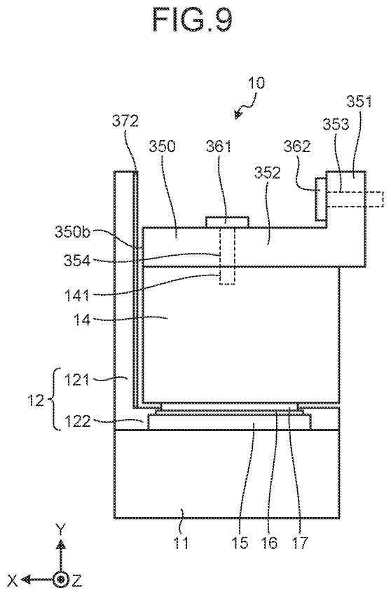

FIG. 9 is a front view of the semiconductor laser module included in the laser oscillator according to the second embodiment, which schematically shows still another example of the configuration of the semiconductor laser module. FIG. 9 also schematically illustrates one of the plurality of semiconductor laser modules 10 illustrated in FIG. 5, viewed from the front side. In FIG. 9, the anode electrode 12 includes an insulating layer 372 on a side surface of the first portion 121, facing the cathode electrode 14 and the bus bar 350. With such a configuration, even when the end portion 350b, which is the X-axis positive side end portion of the fourth portion 352 of the bus bar 350, comes into contact with the first portion 121 of the anode electrode 12, it is possible to prevent the cathode electrode 14 and the anode electrode 12 from being short-circuited via the bus bar 350. Note that although FIG. 9 illustrates the case where the insulating layer 372 is provided on the entire surface of the first portion 121, the insulating layer 372 just needs to be provided at least in a region facing the end portion 350b which is the X-axis positive side end portion of the bus bar 350.

Note that since the third portion 351 of the bus bar 350 is connected to the first portion 121 of the anode electrode 12 of the adjacent semiconductor laser module 10, the first portion 121 of the anode electrode 12 projects upward with respect to the upper surface of the cathode electrode 14.

As described above, the cathode electrodes 14 of the semiconductor laser modules 10 and the anode electrodes 12 of the adjacent semiconductor laser modules 10 are electrically connected in series by use of the bus bars 350. Then, the anode electrode 12 of the semiconductor laser module 10 located at one end of a row of the semiconductor laser modules 10 connected in series and the cathode electrode 14 of the semiconductor laser module 10 located at another end of the row of the semiconductor laser modules 10 connected in series are connected to the power supply. In addition, the bus bar 350 and the cathode electrode 14 is mechanically connected by the screw 361, which is a fastening member, and the bus bar 350 and the anode electrode 12 of the adjacent semiconductor laser module 10 is mechanically connected by the screw 362, which is a fastening member. As a result, the semiconductor laser modules 10 are more firmly fixed in the housing.

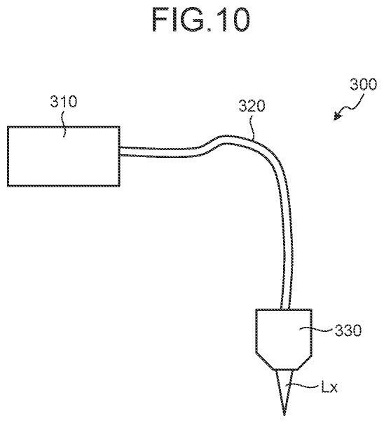

The above-described laser oscillator 310 can be used as a light source of the laser beam Lx of a laser machining apparatus. FIG. 10 is a diagram schematically showing an example of a configuration of a laser machining apparatus according to the second embodiment. A laser machining apparatus 300 includes the laser oscillator 310, an optical fiber 320, and a machining head 330.

The laser oscillator 310 has the configuration described with reference to FIGS. 5 and 6.

The optical fiber 320 transmits, to the machining head 330, the coupled laser beam Lx emitted from the laser oscillator 310.

The machining head 330 condenses the laser beam Lx transmitted through the optical fiber 320, and irradiates a workpiece with the laser beam Lx. The machining head 330 includes a condensing optical system that condenses the laser beam Lx transmitted through the optical fiber 320 and irradiates the workpiece with the laser beam Lx. At the time of machining, the machining head 330 is disposed in such a way as to face a portion of the workpiece to be machined.

The laser oscillator 310 of the second embodiment further includes the L-shaped bus bar 350 connecting the cathode electrode 14 of the semiconductor laser module 10 described in the first embodiment and the anode electrode 12 of the adjacent semiconductor laser module 10. The bus bar 350 is fastened by fastening members, such as the screws 361 and 362, in such a way as to be connected to the upper surface of the cathode electrode 14 and the first portion 121 of the adjacent anode electrode 12. In the semiconductor laser module 10 described in the first embodiment, the heat sink 11 and the anode electrode 12 are fixed by the adhesive 41, and the second portion 122 of the anode electrode 12, the insulating sheet 13, and the cathode electrode 14 are fixed by the adhesives 42 and 43. Therefore, it is not necessary to use a fastening member which would have been conventionally used for fixing the anode electrode 12 and the cathode electrode 14. Thus, the semiconductor laser module 10 can be reduced in width in the X-axis direction as compared with a case where the anode electrode 12 and the cathode electrode 14 are fixed by use of a fastening member. The semiconductor laser modules 10 reduced in width in the X-axis direction as compared with the conventional one in this manner are arranged in the X-axis direction in the laser oscillator 310. This achieves the effect of also enabling the laser oscillator 310 to be miniaturized as compared with the conventional one.

In addition, since the semiconductor laser module 10 is mechanically connected to the adjacent semiconductor laser module by the bus bar 350, the semiconductor laser modules 10 are more firmly fixed to the housing. Furthermore, physical interference with another semiconductor laser module 10 is eliminated if the bus bar 350 is removed. Therefore, when a failure occurs in any of the semiconductor laser modules 10, replacement of the any of the semiconductor laser modules 10 can be performed with fewer man-hours.

Note that, in the above description, when the p-type semiconductor element and n-type semiconductor element of the laser diode element 16 are disposed in reverse, the anode electrode 12 and the cathode electrode 14 are replaced with each other. In this case, the cathode electrode corresponds to the first electrode, and the anode electrode corresponds to the second electrode.

The configurations set forth in the above embodiments show examples, and it is possible to combine the configurations with another known technique or combine the embodiments with each other, and is also possible to partially omit or change the configurations without departing from the scope of the present disclosure.

### REFERENCE SIGNS LIST

10 semiconductor laser module; 11 heat sink; 12 anode electrode; 13 insulating sheet; 14 cathode electrode; 14a, 14b, 350a, 350b end portion; 15 submount; 16 laser diode element; 17 feed structure; 20 laser emission unit; 31 FAC; 32 SAC; 33 manifold; 35, 36, 41, 42, 43 adhesive; 121 first portion; 122 second portion; 124, 141 screw hole; 300 laser machining apparatus; 310 laser oscillator; 311 optical coupler; 312 external resonator mirror; 320 optical fiber; 330 machining head; 331, 353, 354 through-hole; 332 bolt; 350 bus bar; 351 third portion; 352 fourth portion; 361, 362 screw; 371, 372 insulating layer; L, Lx laser beam; R1 electrode placement region; R2 element placement region.

1. A semiconductor laser module comprising:
a heat sink;
a first electrode disposed in a first region of the heat sink;
an insulating layer disposed on the first electrode;
a submount disposed in a second region of the heat sink, the second region being different from the first region, the submount being electrically and thermally conductive;
a laser diode element disposed on the submount, the laser diode element emitting a laser beam;
a feed structure disposed on the laser diode element, the feed structure being electrically and thermally conductive; and
a second electrode provided on the insulating layer and the feed structure such that the second electrode is in contact with the insulating layer and the feed structure, wherein
a positional relationship between the heat sink, the first electrode, the insulating layer, and the second electrode is fixed by an adhesive, and the first electrode is bonded to the second electrode with an insulating adhesive.

2. The semiconductor laser module according to claim 1, wherein
when a Z-axis direction is defined as a direction in which the laser beam is emitted, a Y-axis direction is defined as a direction in which the first electrode and the second electrode are stacked, and an X-axis direction is defined as a direction perpendicular to both the Z-axis and the Y-axis,
the first electrode includes an L-shaped member having a first portion and a second portion, the first portion being parallel to a YZ plane, the second portion being parallel to a ZX plane.

3. A laser oscillator including a plurality of the semiconductor laser modules according to claim 2, the laser oscillator coupling the laser beams emitted from the plurality of semiconductor laser modules and emitting the coupled laser beams, the laser oscillator comprising:
a coupling member that is electrically conductive, the coupling member connecting the second electrode of a first semiconductor laser module and the first electrode of a second semiconductor laser module, the first semiconductor laser module and the second semiconductor laser module being among the plurality of semiconductor laser modules, the second semiconductor laser module being disposed adjacent to the first semiconductor laser module;
a first fastening member to fix the coupling member and the second electrode of the first semiconductor laser module; and
a second fastening member to fix the first electrode of the second semiconductor laser module and the coupling member, wherein
the coupling member includes an L-shaped member having a third portion and a fourth portion, the third portion being parallel to a YZ plane, the fourth portion being parallel to a ZX plane, and
the coupling member is disposed such that the fourth portion is disposed on the second electrode of the first semiconductor laser module, and that the third portion is in contact with the first portion of the first electrode of the second semiconductor laser module.

4. A laser machining apparatus comprising:
the laser oscillator according to claim 3;
an optical fiber to transmit the coupled laser beams emitted from the laser oscillator; and
a machining head to condense the coupled laser beams transmitted through the optical fiber and irradiate a workpiece with the coupled laser beams.
